(19) United States
(12) Patent Application Publication
(10) Pub. No.: US 2024/0186108 A1
(43) Pub. Date: Jun. 6, 2024

(54) Charged Particle Beam System

(71) Applicant: Hitachi High-Tech Corporation, Minato-ku, Tokyo (JP)

(72) Inventors: Hirokazu TAMAKI, Tokyo (JP); Hiromi MISE, Tokyo (JP)

(21) Appl. No.: 17/773,127

(22) PCT Filed: Nov. 22, 2019
(86) PCT No.: PCT/JP2019/045855

§ 371 Date: Apr. 29, 2022

(51) Int. Cl. H01J 37/26; G01N 23/06; G01N 23/2251; H01J 37/20; H01J 37/21

(52) U.S. Cl. CPC H01J 37/265; G01N 23/06; G01N 23/2251; H01J 37/20; H01J 37/21; H01J 2237/1534

(57) ABSTRACT

A charged particle beam system includes a charged particle beam apparatus that irradiates, via a charged particle optical system, a sample with a charged particle beam from a charged particle source and a control system that controls the charged particle ray apparatus. The control system evaluates, with respect to a signal obtained by irradiating the sample with the charged particle beam via the charged particle optical system having an astigmatic aberration, a score based on an index that changes in accordance with a spatial spread of the charged particle beam and determines a positional relation between a height position of the sample and a convergence plane of the charged particle beam based on the astigmatic aberration of the charged particle optical system and a result of the evaluation.

### TECHNICAL FIELD

The present disclosure relates to a charged particle beam system.

### BACKGROUND ART

As a background art of the present application, there is, for example, JP-2009-A-199904 (PTL 1). JP-2009-A-199904 describes “a charged particle beam apparatus comprising: a charged particle optical system to scan a primary charged particle beam onto specimen, detect secondary charged particles emitted from the specimen due to the scanning and output detection results as a secondary charged particle signal; a control unit for the charged particle optical system; an data processing device to process the secondary charged particle signal that was output and acquire two-dimensional distribution information on pixels matching the area scanned by the primary charged particle beam, wherein the charged particle optical system includes: an aberration corrector to reduce the aberration generated by the charged particle optical system; and a unit to guide the charged particle beam from the optical axis of the charged particle beam in a tilted state onto the specimen, and wherein the data processing device calculates the out-of-focus amount and astigmatic difference in the charged particle optical system from the multiple two-dimensional distribution information acquired by scanning the specimen with the primary charged particle in a tilted state and also while changing the degree of focus and, calculates an optional order aberration coefficient generated in the charged particle optical system to use in the charged particle optical system, y utilizing the two-dimensional distribution information obtained from scanning the specimen in a state where the primary charged particle beam is not tilted, and the calculated out-of-focus amount and astigmatic difference” (refer to claim 1).

### CITATION LIST

### Patent Literature

PTL 1: JP-A-2009-199904

### SUMMARY OF INVENTION

### Technical Problem

In the charged particle beam apparatus of the related art, when the focus is out of the specimen during observation and an observed image is blurred, it is difficult to determine in which one of upward and downward directions the focus is out of the specimen by the change of the image alone. For this reason, it is necessary to perform control such as changing the focus in both upward and downward directions when trying to focus from the state in which the focus is out of the specimen, changing the focus in one of the upward and downward directions, or changing the focus in an opposite direction when the focus is further out of the specimen, and focus adjustment takes time. Further, in such a method for searching for a correct focus position by changing the focus, it is necessary to acquire images at a plurality of focuses from the same field of view and compare the acquired images, and thus it is basically not possible to move the field of view when the images are acquired.

### Solution to Problem

The charged particle beam system according to an aspect of the present disclosure includes: a charged particle beam apparatus configured to irradiate, via a charged particle optical system, a sample with a charged particle beam from a charged particle source; and a control system configured to control the charged particle beam apparatus. The control system is configured to evaluate, with respect to a signal obtained by irradiating the sample with the charged particle beam via the charged particle optical system having an astigmatic aberration, a score based on an index that changes in accordance with a spatial spread of the charged particle beam, and determine a positional relation between a height position of the sample and a convergence plane of the charged particle beam based on the astigmatic aberration of the charged particle optical system and a result of the evaluation.

### Advantageous Effect

According to an aspect of the present disclosure, a positional relation between a sample and a focus can be estimated in a charged particle beam apparatus.

### BRIEF DESCRIPTION OF DRAWINGS

FIG. 1 schematically shows a basic configuration of a scanning electron microscope system.

FIG. 2 schematically shows a basic configuration of a system used as a scanning transmission electron microscope.

FIG. 3 shows a hardware configuration example of a computer.

FIG. 4A shows a configuration example of an astigmatic aberration correction device.

FIG. 4B shows an example of changes in a cross-sectional shape of an electron beam in response to changes in a direction and a magnitude of an astigmatic aberration of an electron optical system.

FIG. 5 schematically shows shapes of an electron beam from an electron optical system having no astigmatic aberration and images of a sample at different height positions by the electron beam.

FIG. 6 schematically shows shapes of an electron beam from an electron optical system having a predetermined astigmatic aberration and images of a sample at different height positions by the electron beam.

FIG. 7 shows differential images of the respective images by the electron optical system having no astigmatic aberration.

FIG. 8 shows differential images of the respective images by the electron optical system having an astigmatic aberration.

FIG. 9 shows sharpness scores of the respective images of the electron optical system having no astigmatic aberration.

FIG. 10 shows sharpness scores of the respective images of the electron optical system having an astigmatic aberration.

FIG. 11 shows an example of a control flow of a charged particle beam apparatus by a control system.

FIG. 12 shows another example of the control flow of the charged particle beam apparatus by the control system.

FIG. 13 shows another example of the control flow of the charged particle beam apparatus by the control system.

FIG. 14 shows an example of a graphical user interface for a user to control a charged particle beam system.

FIG. 15A shows an example in which a height distribution in a field of view is evaluated based on an evaluation result of a focus deviation.

FIG. 15B shows an example in which the height distribution in the field of view is evaluated based on the evaluation result of the focus deviation.

FIG. 15C shows an example in which the height distribution in the field of view is evaluated based on the evaluation result of the focus deviation.

FIG. 15D shows an example in which the height distribution in the field of view is evaluated based on the evaluation result of the focus deviation.

FIG. 15E shows an example in which the height distribution in the field of view is evaluated based on the evaluation result of the focus deviation.

FIG. 15F shows an example in which the height distribution in the field of view is evaluated based on the evaluation result of the focus deviation.

FIG. 16 shows a relation among an astigmatic aberration added to an electron optical system, a diameter of a beam cross-sectional shape, and a score when a sample height position is higher than a focus position according to a second embodiment.

FIG. 17 shows the relation among the astigmatic aberration added to the electron optical system, the diameter of the beam cross-sectional shape, and the score when the sample height position is lower than the focus position in the second embodiment.

FIG. 18 shows an example of a control flow of a charged particle beam apparatus by a control system, which corresponds to the examples described with reference to FIGS. 16 and 17.

FIG. 19 shows the relation among the astigmatic aberration added to the electron optical system, the diameter of the beam cross-sectional shape, and the score when evaluation of the focus deviation in a state where the astigmatic aberration is added and display of an observation image acquired in a state where the astigmatic aberration is not added are performed apparently at the same time.

FIG. 20 shows an example of a control flow when the focus deviation is evaluated in two states in which different X parameters are set for the astigmatic aberration correction device and then in a state in which the X parameter is zero.

### DESCRIPTION OF EMBODIMENTS

Hereinafter, embodiments will be described with reference to the accompanying drawings. It should be noted that the embodiments are merely examples for implementing the present disclosure, and do not limit the technical scope of the present disclosure. In the drawings, common components are denoted by the same reference signs. In the following description, an observation apparatus (electron microscope) for a sample that uses an electron beam is shown as an example of a charged particle beam apparatus that irradiates a sample with a charged particle beam. Characteristics of the present disclosure can also be applied to a measurement apparatus or an inspection apparatus in addition to an apparatus using an ion beam.

### First Embodiment

### [System Configuration]

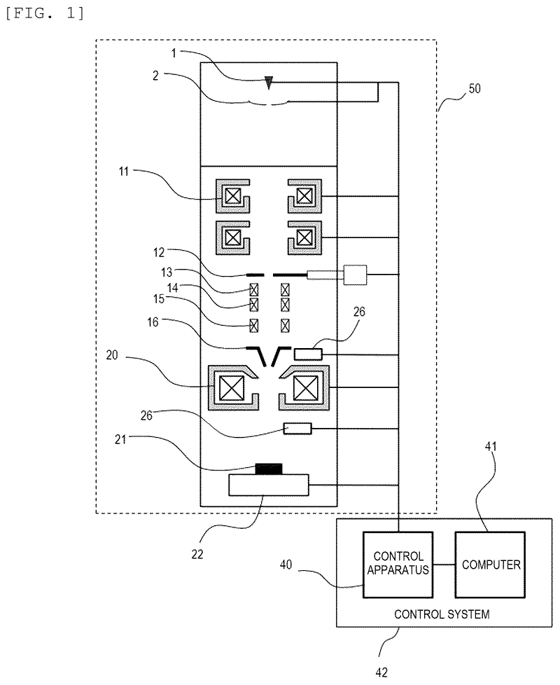

FIG. 1 schematically shows a basic configuration of a scanning electron microscope (SEM) system. The SEM system includes a SEM apparatus 50 and a control system 42. The SEM apparatus 50 is an example of a charged particle beam apparatus and includes an electron beam source 1, an extraction electrode 2, a condenser lens 11, a condenser aperture 12, an axis adjustment deflector 13, an astigmatic aberration correction device 14, a scan deflector 15, and an objective lens 20. In FIG. 1, only one condenser lens is indicated by the sign 11 as an example.

The astigmatic aberration correction device 14 may be a device obtained by combining coils, a device implemented by a multipole, a spherical surface obtained by combining a plurality of multipoles, or a device that performs various types of aberration correction. In addition, each deflector can be used for a predetermined application by combining a plurality of deflectors arranged at different heights.

The electron beam source 1 is an example of a charged particle source and generates a primary electron beam. The condenser lens 11 adjusts a convergence condition of the primary electron beam. The condenser aperture 12 controls a spread angle of the primary electron beam. The axis adjustment deflector 13 adjusts a position of the primary electron beam with respect to the objective lens 20. The astigmatic aberration correction device 14 adjusts a beam shape of the primary electron beam (probe) incident on a sample 21. The scan deflector 15 raster-scans the sample 21 with the primary electron beam. The objective lens 20 adjusts a focus position of the primary electron beam with respect to the sample 21.

The SEM apparatus 50 further includes a sample stage 22, a reflection plate 16, and a detector 26. The sample stage 22 determines a position of the sample 21 in a sample chamber. Electrons generated from the sample 21 or electrons generated by collision of electrons from the sample 21 toward the reflection plate 16 are detected by the detector 26.

The control system 42 controls the SEM apparatus 50. For example, the control system 42 controls an acceleration voltage or an extraction voltage of the primary electron beam and currents of components such as a lens and a deflector. In addition, by controlling the sample stage 22, the control system 42 can adjust a radiation position of the primary electron beam on the sample 21 and a positional relation of the sample 21 with the focus position of the primary electron beam.

The control system 42 controls a gain or an offset of the detector 26 and generates an image by a detected secondary electron beam. As will be described later, the control system 42 evaluates (analyzes) the image and calculates a predetermined score of the image. The control system 42 executes a predetermined process based on the calculated score.

The control system 42 includes a control apparatus 40 and a computer 41. The computer 41 controls components of the SEM apparatus 50 via the control apparatus 40. The computer 41 includes programs, a storage device that stores data used by the programs, and a processor that operates in accordance with the programs stored in the storage device. The programs include a control program and an image processing program for the SEM apparatus 50.

The computer 41 further includes an interface for connecting to a network and a user interface. The user interface includes a display device for displaying an image and an input device for a user to give an instruction to the computer 41. The computer 41 controls the control apparatus 40. The control apparatus 40 includes components an AD converter, a DA converter, a memory, and an arithmetic device such as an FPGA or a microprocessor.

A process of obtaining a SEM image will be described. The extraction electrode 2 extracts the primary electron beam from the electron beam source 1 at a predetermined extraction voltage. A direction parallel to an optical axis is defined as a Z direction, and a plane orthogonal to the optical axis is defined as an XY plane. The control system 42 adjusts the primary electron beam to converge on the sample 21 by adjusting a Z position of the sample stage 22 or adjusting control parameters of the objective lens 20. The adjustment is a rough adjustment.

After the focus rough adjustment, the control system 42 selects a field of view for electron optical system adjustment using an XY movement mechanism of the sample stage 22. At this time, the selection of the field of view may be performed by directly operating the XY movement mechanism of the sample stage 22 by a user of the apparatus. The control system 42 corrects an axis deviation, the focus, and astigmatism in the current field of view for the electron optical system adjustment. Specifically, the control system 42 corrects adjustment parameters of the axis adjustment deflector 13, the astigmatic aberration correction device 14, and the objective lens 20.

Next, the control system 42 uses the sample stage 22 to move a field of view for observation to a field of view for photograph and acquire an image after finely adjusting the focus of the objective lens 20 by a user operation or in an appropriate focus position adjusted by a focus adjustment function so that a sharp image can be observed. As will be described later, by a focus determination function of the control system 42, it is possible to quickly identify an appropriate focus position with respect to a height position of the sample (surface) after the field of view is moved. In addition, when a focus tracking function is ON, the control system 42 can always maintain the focus at an appropriate height position of the sample.

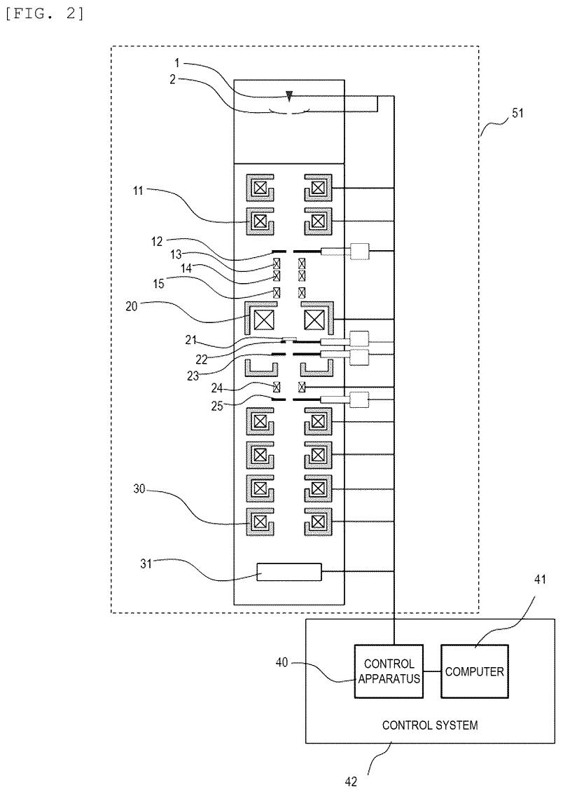

FIG. 2 schematically shows a basic configuration of a system used as a scanning transmission electron microscope (STEM). The STEM system includes a STEM apparatus 51 and the control system 42. The STEM apparatus 51 includes the electron beam source 1, the extraction electrode 2, the condenser lens 11, the condenser aperture 12, the axis adjustment deflector 13, the astigmatic aberration correction device 14, the scan deflector 15, the objective lens 20, and the sample stage 22. In FIG. 2, only one condenser lens is indicated by the sign 11 as an example. Functions of these components are the same as those of the SEM apparatus 50.

The STEM apparatus 51 includes, on a rear side of the sample 21, an objective aperture 23, an axis adjustment deflector 24, a selected area aperture 25, an imaging system lens 30, and a detector 31. In FIG. 2, only one imaging system lens is indicated by the sign 30 as an example. The imaging system lens is not necessarily required to have functions of the STEM. The imaging system lens 30 images a transmitted electron beam transmitted through the sample 21. The detector 31 detects the imaged electron beam.

The control system 42 generates an image by a detected secondary electron beam. As will be described later, the control system 42 evaluates a plurality of images and calculates predetermined evaluation scores at a plurality of positions in each of the images. The control system 42 executes a predetermined process based on the calculated evaluation scores.

Similar to the SEM system, the control system 42 includes the control apparatus 40 and the computer 41. Programs executed by the computer 41 include a control program and an image processing program for the STEM apparatus 51.

A process of obtaining a STEM image will be described. The extraction electrode 2 extracts a primary electron beam from the electron beam source 1 at a predetermined extraction voltage. The control system 42 irradiates the sample 21 on the sample stage 22 with the primary electron beam.

The control system 42 performs the focus rough adjustment on the primary electron beam by adjusting the Z position of the sample stage 22 or adjusting the control parameters of the objective lens 20. Thereafter, the control system 42 selects the field of view for the electron optical system adjustment using the XY movement mechanism of the sample stage 22. The control system 42 corrects the axis deviation, the focus, and an astigmatic aberration in the current field of view for the electron optical system adjustment. Specifically, the control system 42 corrects the adjustment parameters of the axis adjustment deflector 13, the astigmatic aberration correction device 14, and the objective lens 20.

Next, the control system 42 uses the sample stage 22 to move the field of view for observation to the field of view for photograph and capture an image after finely adjusting the focus of the objective lens 20 by the user operation or after adjusting the focus to an appropriate focus position by the focus tracking function so that a sharp image can be observed. As will be described later, by the focus determination function of the control system 42, it is possible to quickly identify the appropriate focus position with respect to the height position of the sample (surface) after the field of view is moved. In addition, when the focus tracking function is ON, the control system 42 can always maintain the focus at an appropriate height position of the sample.

The control system 42 causes the primary electron beam to be incident on the sample 21 using the condenser lens 11, the axis adjustment deflector 13, and the astigmatic aberration correction device 14. The control system 42 performs scanning with the primary electron beam by the scan deflector 15. When the primary electron beam is incident on the sample 21, most electrons transmit through the sample 21. The imaging system lens 30 causes the transmitted electron beam to be incident on the detector 31 at an appropriate angle, and the STEM image is obtained. A magnification of the STEM image is set by a current for controlling the scan deflector 15.

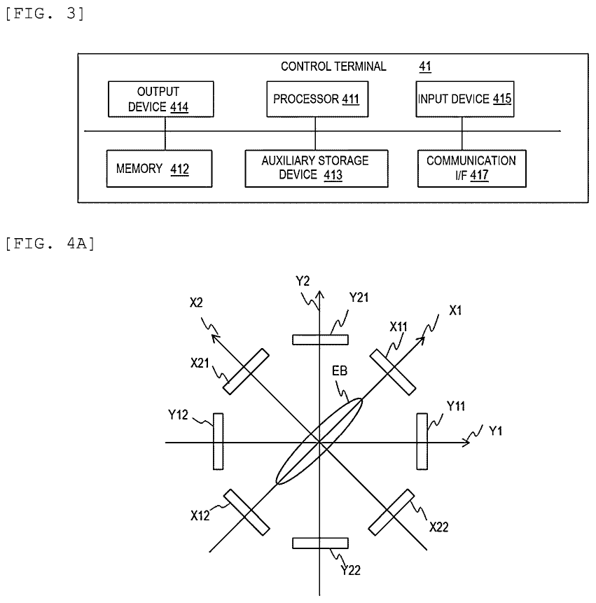

FIG. 3 shows a hardware configuration example of the computer 41. The computer 41 includes a processor 411, a memory (main storage device) 412, an auxiliary storage device 413, an output device 414, an input device 415, and a communication interface (I/F) 417. The above components are connected to one another by a bus. The memory 412, the auxiliary storage device 413, or a combination thereof is a storage device and stores programs and data used by the processor 411.

The memory 412 includes, for example, a semiconductor memory, and is mainly used for storing a program and data during execution. The processor 411 executes various processes in accordance with the programs stored in the memory 412. The processor 411 operates in accordance with the programs, so that various function units are implemented. The auxiliary storage device 413 includes a large-capacity storage device such as a hard disk drive or a solid state drive, and is used for holding the programs and data for a long period of time.

The processor 411 can be implemented by a single processing unit or a plurality of processing units, and can include a single or a plurality of arithmetic units, or a plurality of processing cores. The processor 411 can be implemented as one or a plurality of central processing units, a microprocessor, a microcomputer, a microcontroller, a digital signal processor, a state machine, a logic circuit, a graphic processing unit, a chip-on system, and/or a device that operates a signal based on a control instruction.

The programs and data stored in the auxiliary storage device 413 are loaded into the memory 412 at startup or when needed, and the processor 411 executes the programs, so that various processes of the computer 41 are executed.

The input device 415 is a hardware device for the user to input instructions, information, or the like to the computer 41. The output device 414 is a hardware device that presents various images for input and output, and is, for example, a display device or a printing device. The communication I/F 417 is an interface for connecting to the network.

Functions of the computer 41 can be installed in a computer system that includes one or more computers that include one or more processors and one or more storage devices including a non-transitory storage medium. The plurality of computers communicate via the network. For example, the plurality of functions of the computer 41 may be installed in the plurality of computers.

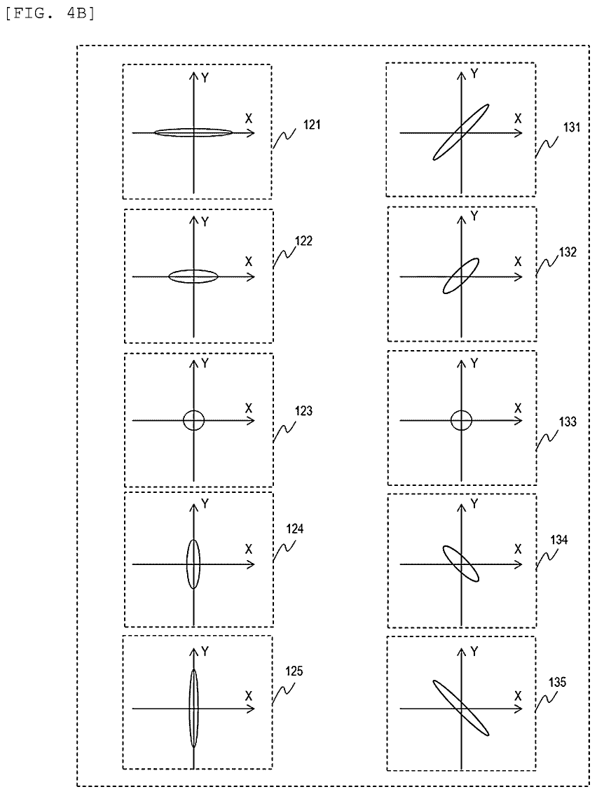

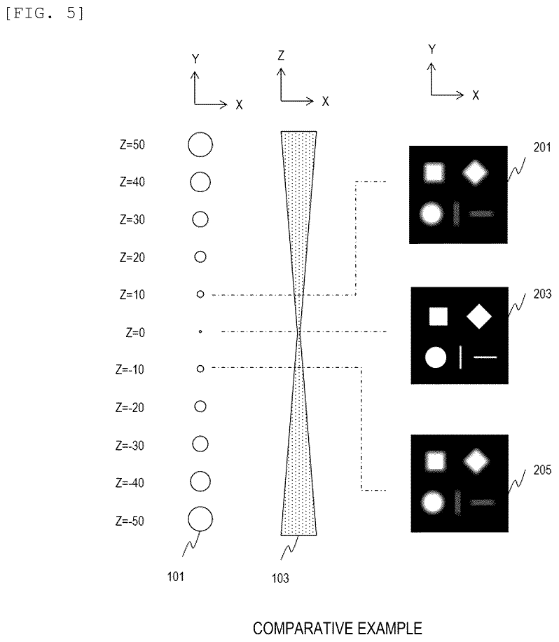

FIG. 4A shows a configuration example of the astigmatic aberration correction device 14. In the configuration example of FIG. 4A, the astigmatic aberration correction device 14 includes octopole coils. The astigmatic aberration correction device 14 includes coils (X-axis astigmatic aberration correction coils) X11, X12, X21, and X22 that correct an astigmatic aberration of an X-axis pair (X1 and X2), and coils (Y-axis astigmatic aberration correction coils) Y11, Y12, Y21, and Y22 that correct an astigmatic aberration of a Y-axis pair (Y1 and Y2).

Each X-axis astigmatic aberration correction coil is arranged at a position rotated by 45 degrees about a center of the optical axis with respect to an arrangement position of the Y-axis astigmatic aberration correction coil. The X-axis astigmatic aberration correction coils X11 and X12 face each other across the center of the optical axis. The X-axis astigmatic aberration correction coils X21 and X22 face each other across the center of the optical axis. The Y-axis astigmatic aberration correction coils Y11 and Y12 face each other across the center of the optical axis. The Y-axis astigmatic aberration correction coils Y21 and Y22 face each other across the center of the optical axis. It is preferable that an intersection of the X1 axis, the X2 axis, the Y1 axis, and the Y2 axis coincides with the center of the optical axis.

The astigmatic aberration correction device 14 uses the octopole coils to deform a cross-sectional shape of an electron beam EB. A direction of a magnetic field generated by the coils and a direction of a force applied to the electron beam by the magnetic field are orthogonal to each other, and thus it is possible to deform the beam in a Y-axis direction (Y1 and Y2) by using the X-axis astigmatic aberration correction coils and deform the beam in an X-axis direction (X1 and X2) by using the Y-axis astigmatic aberration correction coils. As an example, FIG. 4A shows the electron beam EB deformed to be pulled from the center of the optical axis in both positive and negative directions of the X1 axis. The Y-axis astigmatic aberration correction coils are used for correcting an astigmatic aberration of the electron beam EB deformed into such a shape.

The control system 42 causes a current to flow through the Y-axis astigmatic aberration correction coils Y11 and Y12 to generate a flow of magnetic flux in the direction of the optical axis along the Y1 axis. At the same time, the control system 42 causes a current to flow in an opposite direction through the Y-axis astigmatic aberration correction coils Y21 and Y22 to generate a magnetic field in a direction opposite to the Y axis on the Y2 axis. As a result, on the X1 axis, a magnetic field is generated in a direction orthogonal to the X1 axis and in directions from Y11 to Y21 and from Y12 to Y21 so that the electron beam EB is compressed along a major axis direction of an ellipse (X1 axis), and on the X2 axis, a magnetic field is generated in a direction orthogonal to the X2 axis and in directions from Y12 to Y21 and from Y11 to Y22 so that the electron beam EB diverges along the major axis direction of the ellipse (X2 axis). As a result, the electron beam EB passed through the correction magnetic field generated by the astigmatic aberration correction coils is corrected into a circular shape.

When an electron beam having an elliptical cross section having a major axis coinciding with the Y1 axis or the Y2 axis and a minor axis coinciding with the Y2 axis or the Y1 axis is corrected, the control system 42 uses the X-axis astigmatic aberration correction coils. Specifically, the control system 42 causes a current to flow through the X-axis astigmatic aberration correction coils X11 and X12 to generate a flow of magnetic flux in a direction toward the optical axis or in a direction away from the optical axis along the X1 axis. At the same time, the control system 42 causes a current to flow in an opposite direction through the X-axis astigmatic aberration correction coils X21 and X22 to generate a magnetic field in a direction opposite to the X1 axis on the X2 axis. Accordingly, it is possible to correct the electron beam to have a circular cross section.

For example, the control system 42 specifies a current of the X-axis astigmatic aberration correction coils (X parameter) and a current of the Y-axis astigmatic aberration correction coils (Y parameter) to control the astigmatic aberration correction device 14. The astigmatic aberration correction device 14 applies a current to each correction coil in accordance with the specified X and Y parameters.

Further, in the above-described description, the example of the astigmatic aberration correction using the coils is described. Alternatively, the same adjustment can be performed by using electrodes instead of the coils and using an action by an electric field. In this case, there is only one difference from the case of using the magnetic field that the electron beam deforms in accordance with directions of electrodes to be controlled, and the same control is performed for the other points, so that the same effect can be obtained. In the above description, the example of the astigmatic aberration correction using the octopole coils is described.

Alternatively, by using different numbers of multipole coils such as 12-pole coils, it is possible to correct an aberration having different symmetries.

### [Focus Adjustment]

Hereinafter, a method for evaluating the focus position of the SEM apparatus 50 or the STEM apparatus 51 based on analysis of the image acquired by the SEM apparatus 50 or the STEM apparatus 51 (hereinafter, referred to as charged particle beam apparatus) and a result of the image analysis and adjusting the focus position as necessary will be described. The focus position can be controlled by a current of the objective lens 20. It is possible to adjust a vertical position of the focus with respect to the sample by adjusting the objective lens current.

For example, the control system 42 acquires one image of the sample at a certain focus position in a state where at least the direction of an astigmatic aberration in the electron optical system of the charged particle beam apparatus is known with a certain degree of accuracy or more. Further, the computer 41 evaluates a sharpness of the acquired image. The computer 41 further estimates a relation between the focus position and the height position of the sample based on the known astigmatic aberration and a value of the sharpness.

The relation between the focus position and the height position of the sample can be estimated as long as the accuracy of the known information related to the direction of the astigmatic aberration required at this time is within +45° in a case of being converted into a direction of extension of the electron beam due to the astigmatic aberration and a sign of an astigmatic aberration coefficient can be distinguished when the astigmatic aberration coefficient is expressed by positive and negative. Further, as the direction of the astigmatic aberration is known at higher accuracy and a magnitude of the astigmatic aberration is better known, the accuracy in the determination is improved.

Specifically, the computer 41 calculates scores of respective sharpnesses along two axes in the image using an anisotropic filter and estimates the relation between the height position of the sample and the focus position based on these scores and the information related to the known astigmatic aberration. Each score represents a steepness or a maximum value of an intensity change of the image along the axis included in the image, or a height of a spatial frequency corresponding to a predetermined reference.

As described below, the computer 41 estimates how far the focus position is away from an upper side or a lower side of the sample. In the following description, the electron beam source 1 side is the upper side of the sample, an opposite side thereof is the lower side of the sample, and a position along the vertical direction with respect to the sample is referred to as the height. The computer 41 may estimate that the focus position is located on the upper side or the lower side of the sample alone, and may not estimate a distance between the focus position and the sample.

The computer 41 may also evaluate an index that is different from the sharpness and changes in accordance with a spatial spread. As an example thereof, it is possible to use a spread of a frequency intensity spectrum in a specific direction, a spread of a peak intensity generated in an autocorrelation coefficient and a cross-correlation coefficient obtained from an image in a specific direction, or the like in a result of Fourier transform of the image. In addition, the computer 41 may acquire a signal different from a two-dimensional image signal, for example, a one-dimensional signal and evaluate the index that changes in accordance with the spatial spread of the signal, thereby determining the relation between the height position of the sample and the focus position (position of a convergence plane of the beam).

FIG. 4B is an example showing, when the direction and the magnitude of the astigmatic aberration of the electron optical system change, how the cross-sectional shape of the electron beam changes on a plane at a specific height corresponding to a portion on which the electron beam converges. A cross section 121 to a cross section 125 show an example in which the direction of the astigmatic aberration is 0° and the magnitude of the astigmatic aberration changes. For example, the cross section 123 has an astigmatic aberration amount of 0, the cross section 122 has an astigmatic aberration amount of 1, the cross section 121 has an astigmatic aberration amount of 2, the cross section 124 has an astigmatic aberration amount of −1, and the cross section 125 has an astigmatic aberration amount of −2.

A cross section 131 to a cross section 135 show an example in which the direction of the astigmatic aberration is 45° and the magnitude of the astigmatic aberration changes. For example, the cross section 133 has an astigmatic aberration amount of 0, the cross section 132 has an astigmatic aberration amount of 1, the cross section 131 has an astigmatic aberration amount of 2, the cross section 134 has an astigmatic aberration amount of −1, and the cross section 135 has an astigmatic aberration amount of −2.

A unit of the aberration amount and a scale of an absolute amount of the aberration at this time may take various forms depending on conditions and ways of taking the reference. As another method of expressing the aberration, when the magnitude of the aberration is expressed by a positive numerical value, the cross section 124 also can be expressed as an aberration having a magnitude 1 in a 90° direction, the cross section 125 also can be expressed as an aberration having a magnitude 2 in the 90° direction, the cross section 134 also can be expressed as an aberration having the magnitude 1 in a 135° direction, and the cross section 135 also can be expressed as an aberration having the magnitude 2 in the 135° direction.

In a case of a second-order astigmatic aberration, since the second-order astigmatic aberration has a rotational symmetry of 180°, an aberration in a 0° direction is substantially the same as an aberration in a 180° direction. Based on this, an angle region in which the major axis direction of the beam cross section changes in a range of 0° to 180° is treated as one cycle of the direction of the aberration, and it is also possible to express the direction by additionally assigning an angle of 0° to 360° or −180° to 180° to this one cycle. In addition, it is also possible to use a plurality of expressions in which an aberration amount having any direction and magnitude is decomposed into components in two orthogonal directions and the components are set as a real part and an imaginary part, respectively. The direction of such an aberration is also expressed as phase.

FIG. 5 schematically shows a part where an electron beam converges by the electron optical system having no astigmatic aberration or having an astigmatic aberration small enough to ignore an influence thereof and images obtained when the sample is observed at different height positions by the current electron beam.

In FIG. 5, a sign 103 denotes a cross section of an electron beam having one convergence point with a Z axis as the optical axis on a plane including the Z axis and the X axis. Further, a sign 101 and a plurality of circles shown above the sign 101 indicate cross-sectional shapes of the electron beam on a plurality of different planes on the Z axis, and a horizontal direction and a vertical direction of the figure correspond to an X-axis direction and a Y-axis direction, respectively. A position on the Z axis corresponding to each cross-sectional shape 101 when a position at which the beam converges is defined as the reference (Z=0) is shown on a left side of the cross-sectional shape 101, and a unit is, for example, μm. A position above the focus position is indicated by a positive number, and a position below the focus position is indicated by a negative number. The X axis, the Y axis, and the Z axis are perpendicular to one another.

Since the electron optical system of the charged particle beam apparatus has no astigmatic aberration, the beam cross-sectional shape 101 at any height position (position on the Z axis) is a circle. In FIG. 5, the beam cross-sectional shape at one height position is indicated by the sign 101 as an example. A diameter of the beam cross-sectional shape is smallest at the focus position (Z=0) and increases as the height position of the sample is away from the focus position.

Therefore, an image 203 in which the height position of the sample coincides with the focus position (Z=0) of the electron beam 103 is the sharpest. An image 201 in which the height position of the sample is above the focus position (Z=10) and an image 205 in which the height position of the sample is below the focus position (Z=−10) are both blurred compared with the image 203 at the focus position, and the sharpnesses thereof are low. At this time, since the electron optical system has no astigmatic aberration, the blurs of the images 201 and 205 are isotropic.

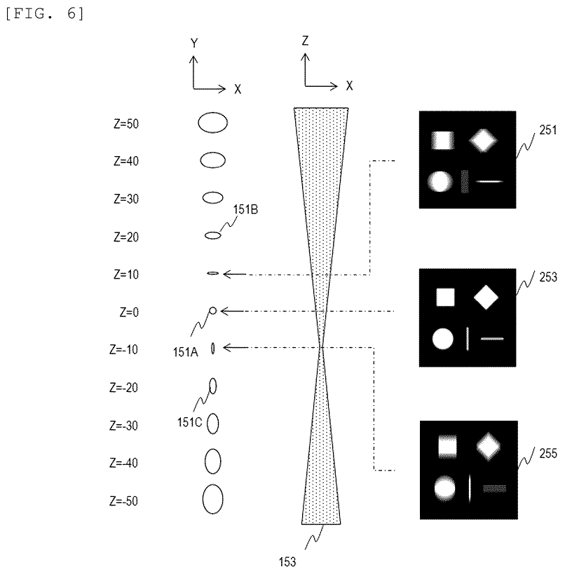

FIG. 6 schematically shows the shape of the electron beam in a state where a predetermined astigmatic aberration is added to the electron optical system with respect to the electron beam shown in FIG. 5, and images of the sample at different height positions by the current electron beam. A sign 153 denotes a cross section of the electron beam on a plane including the Z axis and the X axis. The optical axis of the electron beam coincides with the Z axis, and the X axis, the Y axis, and the Z axis are perpendicular to one another.

A value of Z shown on the left of FIG. 6 shows a position on the Z axis, and a state shown in FIG. 6 is a state where the electron optical system has no astigmatic aberration. That is, a plurality of circles shown by 151A, 151B, and 151C shown in FIG. 5 show the cross-sectional shapes of the electron beam in a plurality of different planes on the Z axis, and the horizontal direction and the vertical direction of the figure correspond to the X-axis direction and the Y-axis direction, respectively. The position on the Z axis corresponding to each figure is shown on the left, and a unit is, for example, μm. The position on the Z axis shown in FIG. 5 and the position on the Z axis shown in FIG. 6 are the same position, and comparing the beam cross-sectional shapes at the same position on the Z axis shown in FIG. 5 and FIG. 6 corresponds to evaluating change of the beam cross-sectional shape on the same plane on the Z axis before and after a predetermined astigmatic aberration is added.

In FIG. 6, the beam cross-sectional shape 151A at a position at which Z=0 is a circle. Since the electron optical system of the charged particle beam apparatus has an astigmatic aberration, a diameter of the beam cross-sectional shape 151A at the position at which Z=0 is larger than a diameter of the beam cross-sectional shape at the position where Z=0 of the electron optical system having no astigmatic aberration. An image 253 in which the height position of the sample coincides with the position at which Z=0 is slightly blurred as compared with the image 203 at the position at which Z=0 of the electron optical system having no astigmatic aberration.

In the electron optical system having an astigmatic aberration, a beam cross-sectional shape at a position different from the position at which Z=0 is different from a circle. The astigmatic aberration shown in FIG. 6 is a first order astigmatic aberration or a two-fold symmetry astigmatic aberration, and a beam cross-sectional shape at a height position different from the position at which Z=0 is an ellipse.

In FIG. 6, one beam cross-sectional shape at a position higher than the position at which Z=0 is indicated by the sign 151B, and a major axis coincides with the X axis and a minor axis coincides with the Y axis. In addition, one beam cross-sectional shape at a position lower than the position at which Z=0 is indicated by the sign 151C, and a major axis coincides with the Y axis and a minor axis coincides with the X axis.

The beam cross-sectional shape has a smallest diameter on the Y axis at a height position Z=10. As the height position is away from Z=10, the diameter on the Y axis increases. The height position Z=10 can be regarded as a focus position on the Y axis. In addition, the beam cross-sectional shape has a smallest diameter on the X axis at a height position Z=−10. As the height position is away from Z=−10, the diameter on the X axis increases. The height position Z=−10 can be regarded as a focus position on the X axis.

Accordingly, it can be seen that in the electron optical system having no astigmatic aberration, the cross-sectional shape of the beam is circular and isotropic near above and below the focus position, whereas in a state where the optical system has an astigmatic aberration, the cross-sectional shape of the beam is anisotropic near above and below the focus position, and the direction thereof changes above and below the focus position.

As compared with the image 253 at the position at which Z=0, an image 251 when the height position of the sample is Z=10 has a larger blur along the X axis and a smaller blur along the Y axis. Therefore, a sharpness along the X axis is low and a sharpness along the Y axis is high. This is because the diameter on the X axis of the beam cross-sectional shape at the height position Z=10 is larger than the diameter at the position at which Z=0 and the diameter on the Y axis of the beam cross-sectional shape at the height position Z=10 is smaller than the diameter of the position at which Z=0.

In addition, as compared with the image 253 at the position at which Z=0, an image 255 when the height position of the sample is Z=−10 has a smaller blur along the X axis and a larger blur along the Y axis. Therefore, the sharpness along the X axis is high and the sharpness along the Y axis is low. This is because the diameter on the Y axis of the beam cross-sectional shape at the height position Z=−10 is larger than the diameter at the position at which Z=0 and the diameter on the X axis of the beam cross-sectional shape at the height position Z=−10 is smaller than the diameter of the position at which Z=0.

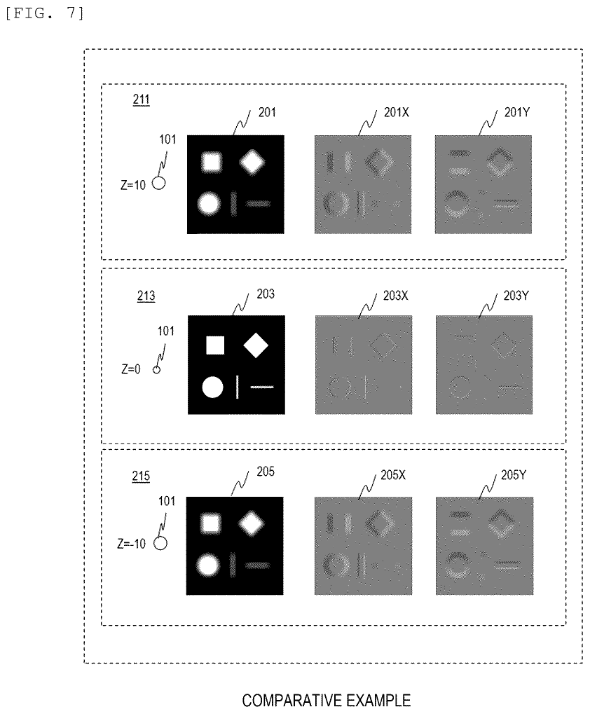

FIG. 7 shows differential images of the respective images 201, 203, and 205 by the electron optical system having no astigmatic aberration. An image group 211 includes the image 201 when the height position of the sample is Z=10, a differential image 201X along an X axis of the image 201, and a differential image 201Y along a Y axis of the image 201.

An image group 213 includes the image 203 when the height position of the sample is at the focus position (Z=0), a differential image 203X along an X axis of the image 203, and a differential image 203Y along a Y axis of the image 203. An image group 215 includes the image 205 when the height position of the sample is Z=−10, a differential image 205X along an X axis of the image 205, and a differential image 205Y along a Y axis of the image 205.

The differential image indicates a change (sharpness) in an image intensity (luminance) along a corresponding axis, and the intensity (luminance) becomes higher as a gradient of the intensity of an original image becomes steeper. In FIG. 7, the differential image 203X at the focus position shows a maximum intensity higher than those of the other differential images 201X and 205X along the X axis. In addition, the differential image 203Y at the focus position shows a maximum intensity higher than those of the other differential images 201Y and 205Y along the Y axis. This indicates that diameters along the X axis and the Y axis of the beam cross section at the focus position are smaller than diameters along the X axis and the Y axis of the beam cross section at the other height positions, and the obtained images are sharp in the respective directions of the X axis and the Y axis.

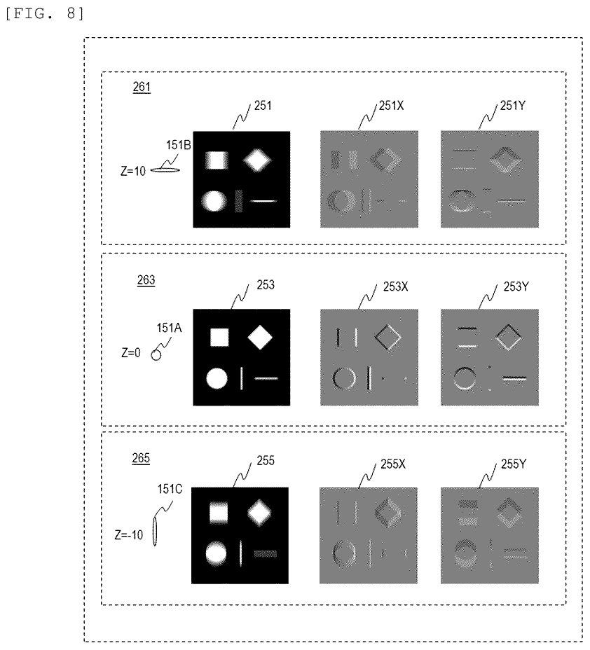

FIG. 8 shows differential images of the respective images 251, 253, and 255 by the electron optical system having an astigmatic aberration. An image group 261 includes the image 251 when the height position of the sample is Z=10, a differential image 251X along an X axis of the image 251, and a differential image 251Y along a Y axis of the image 251.

An image group 263 includes the image 253 when the height position of the sample is at the focus position (Z=0), a differential image 253X along an X axis of the image 253, and a differential image 253Y along a Y axis of the image 253. An image group 265 includes the image 255 when the height position of the sample is Z=−10, a differential image 255X along an X axis of the image 255, and a differential image 255Y along a Y axis of the image 255.

In FIG. 8, the differential image 251Y along the Y axis at the height position Z=10 shows a maximum intensity higher than those of the other differential images 253Y and 255Y along the Y axis. This indicates that a diameter along the Y axis of the beam cross section at the height position Z=10 is smaller than diameters along the Y axis of the beam cross sections at the other height positions, and the obtained image is sharp in the Y-axis direction.

In addition, the differential image 255X along the X axis at the height position Z=−10 shows a maximum intensity higher than those of the other differential images 251X and 253X along the X axis. This indicates that a diameter along the X axis of the beam cross section at the height position Z=−10 is smaller than diameters along the X axis of the beam cross sections at the other height positions, and the obtained image is sharp in the X-axis direction.

As described above, the images obtained by the beams obtained by the electron optical system having an astigmatic aberration have an anisotropy in the sharpness depending on the height position of the sample with respect to the focus position. In the examples shown in FIGS. 6 and 8, the image of the sample at a position higher than the focus position (Z=0) shows a higher sharpness along the Y axis and a lower sharpness along the X axis. In addition, the image of the sample at a position lower than the focus position (Z=0) shows a higher sharpness along the X axis and a lower sharpness along the Y axis. The computer 41 evaluates the anisotropy of the sharpness in the image in the electron optical system having an astigmatic aberration, and estimates the relation between the height position of the sample and the focus position when the current image is acquired.

In order to evaluate the anisotropy of the sharpness of the image, the computer 41 calculates sharpness scores in two different axes. A high sharpness in one axis means that the diameter of the beam cross-sectional shape in the axis is small. The two axes coincide with, for example, a major axis and a minor axis of an elliptical beam cross-sectional shape. Accordingly, it is possible to obtain a sharpness score that is effective for estimating the height position of the sample. In addition, by adding an astigmatic aberration in an appropriate direction to the electron optical system, it is possible to cause the major axis and the minor axis of the elliptical beam to coincide with the directions corresponding to the two axes constituting the image. In this case, an arithmetic process for evaluating the sharpness in each of the directions of the two axes of the image is simple. In order to calculate the sharpness score, other two axes may be selected. Two axes having different diameters of the beam cross-sectional shape at a height position different from the focus position are selected. The two axes may not be orthogonal to each other.

Next, a method for estimating the relation between the height position of the sample and the focus position from the sharpness scores of the two axes will be described. In an example described below, the relation between the height position of the sample and the focus position is estimated from a sharpness score on the X axis (X sharpness score) and a sharpness score on the Y axis (Y sharpness score) shown in FIGS. 5 to 8. Details of a method for calculating the sharpness score will be described later, and it is possible to obtain an appropriate sharpness score by the wavelet transform or the differential filter.

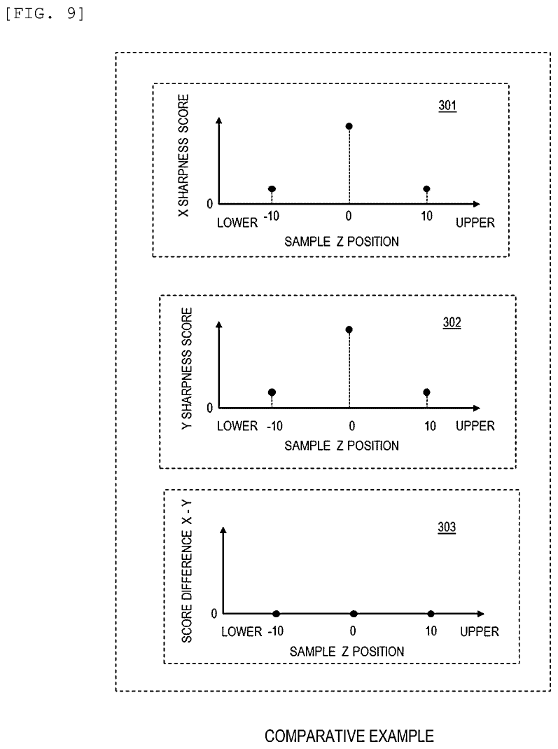

FIG. 9 shows sharpness scores of the respective images of the electron optical system having no astigmatic aberration. In a graph 301, a horizontal axis represents the height position of the sample (position on the Z axis), and a vertical axis represents the X sharpness score of the image. Each point shows the X sharpness score of a corresponding one of the images 201, 203, and 205. The X sharpness score of the image 203 of the sample at the focus position (Z=0) is the highest, and the X sharpness scores of the images 201 and 205 of the sample at the positions above and below the focus position (Z=−10, 10) are low.

In a graph 302, a horizontal axis represents the height position of the sample (position on the Z axis), and a vertical axis represents the X sharpness score of the image. Each point shows the Y sharpness score of a corresponding one of the images 201, 203, and 205. The Y sharpness score of the image 203 of the sample at the focus position (Z=0) is the highest, and the Y sharpness scores of the images 201 and 205 of the sample at the positions above and below the focus position (Z=−10, 10) are low.

A graph 303 shows a value obtained by subtracting the Y sharpness score from the X sharpness score of each image. The sharpness in each direction in the electron optical system having no astigmatic aberration is almost the same, and a decrease in the sharpness in each direction generated when the focus position is away from the height position of the sample hardly depends on the direction in which the focus position is away from the height position of the sample but depends on a separation distance alone. Therefore, the value obtained by subtracting the Y sharpness score from the X sharpness score at each height is a value close to zero at any height.

When cases other than the focus deviation (defocus) and a first-order astigmatic aberration among the aberrations of the optical system are considered, change in the sharpness when the focus position is away from the height position of the sample shows certain dependence on the direction in which the focus position is away from the height position of the sample. However, in a state in which a general electron microscope is adjusted appropriately, a third-order spherical aberration alone may have such an influence, and the influence can be almost ignored in addition to observation at such a high magnification that a size of pixels constituting an observation image is substantially equal to or less than an amount of the third-order spherical aberration. In addition, even in the observation at a high magnification as described above, the behavior described above based on the astigmatic aberration is similarly generated, and thus the effect described in the invention does not greatly change in many situations.

FIG. 10 shows sharpness scores of the respective images of the electron optical system having an astigmatic aberration. In a graph 351, a horizontal axis represents the height position of the sample (position on the Z axis), and a vertical axis represents the X sharpness score of the image. Each point shows the X sharpness score of a corresponding one of the images 251, 253, and 255. The X sharpness score of the image 255 of the sample at a position (Z=−10) lower than the position at which Z=0 is the highest, and the X sharpness score of the image 251 of the sample at a position (Z=10) higher than the position at which Z=0 is the lowest.

In a graph 352, a horizontal axis represents the height position of the sample (position on the Z axis), and a vertical axis represents the X sharpness score of the image. Each point shows the Y sharpness score of a corresponding one of the images 251, 253, and 255. The Y sharpness score of the image 251 of the sample at the position (Z=10) higher than the position at which Z=0 is the highest, and the X sharpness score of the image 255 of the sample at the position (Z=−10) lower than the position at which Z=0 is the lowest.

A graph 353 shows a value obtained by subtracting the Y sharpness score from the X sharpness score of each image. A value of the image of the sample at the position (Z=−10) lower than the position at which Z=0 is positive and is the largest. A value of the image of the sample at the position at which Z=0 is close to zero because the X sharpness score and the Y sharpness score are close to each other. A value of the image of the sample at the position (Z=10) higher than the position at which Z=0 is negative and is the smallest.

As described above, in the electron optical system having an astigmatic aberration, the X sharpness score decreases as the height position of the sample approaches Z=10 from Z=−10, and the Y sharpness score increases as the height position of the sample approaches Z=10 from Z=−10. When the sample is at the position at which Z=0, the X sharpness and the Y sharpness of the image have the same value. When the sample is at the position higher than the position at which Z=0, the Y sharpness of the image is high and the X sharpness is low. In contrast, when the sample is at the position lower than the position at which Z=0, the X sharpness of the image is high and the Y sharpness is low.

As described above, a relation between the X sharpness score and the Y sharpness score changes in accordance with the height position of the sample, and thus it is possible to obtain information on a deviation (focus deviation) between the height position of the sample and the position at which Z=0, for example, presence and absence of the focus deviation, a direction of the deviation, and a magnitude of the deviation from the relation between the X sharpness score and the Y sharpness score. In evaluation of the relation between the scores, magnitudes of the respective scores are compared. In order to compare the magnitudes of the respective scores, it is possible to use a difference, a ratio, or a quotient of the scores. In an example, a difference between the X sharpness score and the Y sharpness score can be used as the score of the focus deviation.

In the example shown in FIG. 10, when the focus deviation score shown by the graph 353 is positive, the focus is above the sample. In contrast, when the focus deviation score is negative, the focus is below the sample. As described above, the computer 41 can estimate the direction of the focus deviation from the positive and negative of the focus deviation score.

In a case where the focus or the sample position is changed in such a direction that the estimated focus deviation becomes small, and the same focus deviation estimation is performed again, a sign of the focus deviation score does not change, and it is expected that the magnitude thereof alone is slightly reduced. By repeatedly performing such an operation, a distance between the position at which Z=0 and the height position of the sample is gradually decreased, and finally, the position at which Z=0 (the position at which the electron beam converges when the optical system has no astigmatic aberration) and the height position of the sample can be matched with each other at an accuracy equal to or less than a predetermined value.

In addition, in a case where a focus deviation amount is larger than half of an astigmatic difference amount determined by the astigmatic aberration amount of the optical system, that is, half of a distance between planes at which the beam width is minimum in the respective directions at the upper and lower sides of the position at which Z=0 (astigmatic difference), one of the two obtained sharpnesses may indicate change that the sharpness decreases with the distance from the sample increases. Even in such a case, the sign of the score obtained from the sharpness or the direction of the deviation from a reference value does not change, and thus it is possible to finally match the position at which Z=0 and the height position of the sample with each other at the accuracy equal to or less than a predetermined value by continuing the control based on the score.

As a more specific control method, feedback on the focus may be performed by multiplying an estimated focus deviation score by a coefficient according to an observation magnification, a target adjustment accuracy, and a speed, or adding a result thereof to a current value or voltage value that controls the objective lens or the lens used for focus adjustment.

Further, the computer 41 can estimate the focus deviation amount (distance) from an absolute value of the focus deviation score. As described above, in the electron optical system having an astigmatic aberration, under a focused condition, the sharpnesses in two axial directions are close to each other and a difference between the two sharpnesses is a minimum value close to zero, and as the focus deviates from that state, the sharpnesses in the two axial directions increase in each of the positive and negative directions, and the difference between the two sharpnesses increases, and thus it is possible to estimate a deviation amount of the focus position from the height position of the sample from a magnitude of an absolute value of the difference.

In this case, the computer 41 can estimate the focus deviation amount by holding information indicating a relation between the focus deviation score and the focus deviation amount, which is set in advance, and comparing the information with the measured score of the focus deviation. These relations can be identified in advance by measurement of the focus deviation amount using a measurement sample, measurement based on a movement amount of the sample stage, or the like.

In addition, as another method for estimating the focus deviation amount from the score of the focus deviation, it is also possible to estimate the focus deviation amount based on the score of the focus deviation measured at a plurality of different focus positions or height positions. When a method for determining the sharpness to be used for determining the focus deviation score is performed by an appropriate way, the change in the score of the focus deviation with respect to the focus deviation amount is not linear, and thus it is possible to estimate the absolute value of the focus deviation amount from an amount of change in the score of the focus deviation with respect to change in a predetermined amount of focus position (inclination in the graph with respect to both).

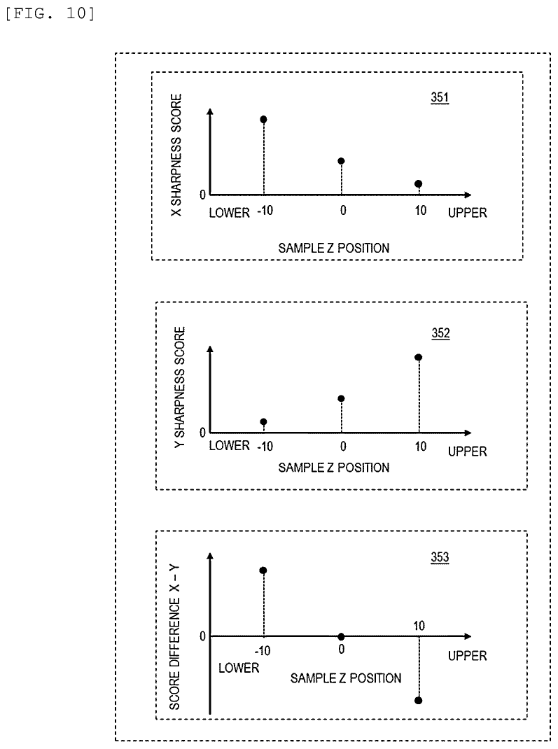

FIG. 11 shows an example of a control flow of the charged particle beam apparatus by the control system 42. In the present example, upon detecting a user operation of the sample stage 22 for moving the field of view, the control system 42 adjusts a relative position between the sample and the focus based on the focus deviation score of the acquired image.

Accordingly, it is possible to maintain the focus position with respect to the sample at an appropriate position for recognizing the sample even when the field of view is moved, and it is also possible to observe or photograph an image under appropriate conditions without performing focus adjustment again after the field of view is moved. In addition, even when the focus position is adjusted with finer accuracy after the movement of the field of view, it is possible to efficiently perform the adjustment by changing the direction in which the focus position approaches the sample alone by using the information on the direction and the magnitude of the focus deviation determined so far using the method described above.

After the electron optical system adjustment of the charged particle beam apparatus is performed, the control system 42 receives a stage control operation from the user (S101), and then adds a predetermined astigmatic aberration using the astigmatic aberration correction device 14 (S102). When the astigmatic aberration of the electron optical system has been corrected to a predetermined amount or below before the astigmatic aberration is added, by adding a predetermined known astigmatic aberration, the control system 42 can freely adjust the magnitude and direction of the astigmatic aberration of the electron optical system within a range that can be handled by the astigmatic aberration correction device. A relation between the astigmatic aberration and the X and Y parameters of the astigmatic aberration correction of the astigmatic aberration correction device 14 necessary for adding the astigmatic aberration having a predetermined amount and direction can use a value measured or designed in advance. It is possible to estimate the focus deviation more accurately by adding an astigmatic aberration in accordance with a magnification, a required adjustment accuracy, and a speed of moving the field of view.

Next, the control system 42 controls the stage in accordance with the stage control operation from the user and moves the sample (S103). The control system 42 acquires an observation image (S104). The control system 42 evaluates the acquired image and acquires the X and Y sharpness scores (S105). The control system 42 calculates the focus deviation score from the X and Y sharpness scores (S106).

The control system 42 feedbacks the focus deviation score to an objective lens current value or a height position of the sample stage 22 (S107). The control system 42 estimates the positional relation between the sample and the focus, specifically, whether the focus is located on the upper side or the lower side with respect to the sample from the focus deviation score, and also estimates how far the focus is away from the sample as necessary. The control system 42 controls the objective lens current value or the height position of the sample stage 22 in accordance with the estimation result so that the focus approaches the sample.

It should be noted that one or both of the objective lens current value and the height position of the stage may be adjusted, and for example, the relative position between the focus and the sample may be adjusted by controlling a parameter different from the objective lens current value and the height position of the stage, such as a lens other than the objective lens that constitutes the optical system. The same applies to other flowcharts that will be described later.

While the stage control operation from the user is continued (S108: YES), the control system 42 continues to execute steps S103 to S107. When the stage control operation from the user is ended (S108: NO), the control system 42 returns a state of the astigmatic aberration correction device 14 to a state before the astigmatic aberration is added, and eliminates the added astigmatic aberration (S109).

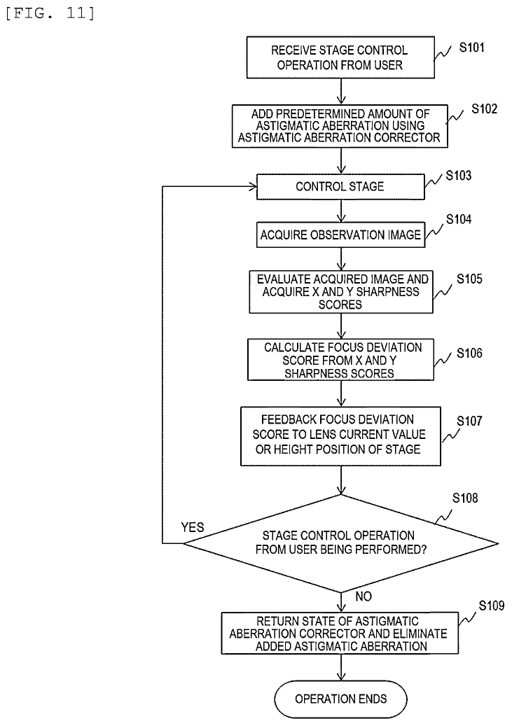

FIG. 12 shows another example of the control flow of the charged particle beam apparatus by the control system 42. In the present example, upon detecting that the focus tracking function is enabled, the control system 42 adjusts the relative position between the sample and the focus based on the focus deviation score of the acquired image. Accordingly, it is possible to efficiently align the focus with respect to the sample.

After the electron optical system adjustment of the charged particle beam apparatus is performed, the control system 42 receives a user operation for enabling the focus tracking function (S121), and then adds a predetermined amount of the astigmatic aberration using the astigmatic aberration correction device 14 (S122). When the astigmatic aberration of the electron optical system has been corrected to the predetermined amount or below before the astigmatic aberration is added, by adding the predetermined known astigmatic aberration, the control system 42 can freely adjust the magnitude and direction of the astigmatic aberration of the electron optical system within a range that can be handled by the astigmatic aberration correction device. A relation between an astigmatic aberration desired to be added and the X and Y parameters of the astigmatic aberration correction of the astigmatic aberration correction device 14 is set in advance. It is possible to estimate the focus deviation more accurately by adding the desired astigmatic aberration.

The control system 42 acquires the observation image (S123). The control system 42 evaluates the acquired image and acquires the X and Y sharpness scores (S124). The control system 42 calculates the focus deviation score from the X and Y sharpness scores (S125).

The control system 42 feedbacks the focus deviation score to an objective lens current value or a height position of the sample stage 22 (S126). The control system 42 estimates the positional relation between the sample and the focus, specifically, whether the focus is located on the upper side or the lower side with respect to the sample from the focus deviation score, and also estimates how far the focus is away from the sample as necessary. The control system 42 controls the objective lens current value or the height position of the sample stage 22 in accordance with the estimation result so that the focus approaches the sample.

While the focus tracking function is enabled (S127: NO), the control system 42 continues to execute steps S123 to S126. When the focus tracking function is disabled (S127: YES), the control system 42 returns the state of the astigmatic aberration correction device 14 to the state before the astigmatic aberration is added, and eliminates the added astigmatic aberration (S128).

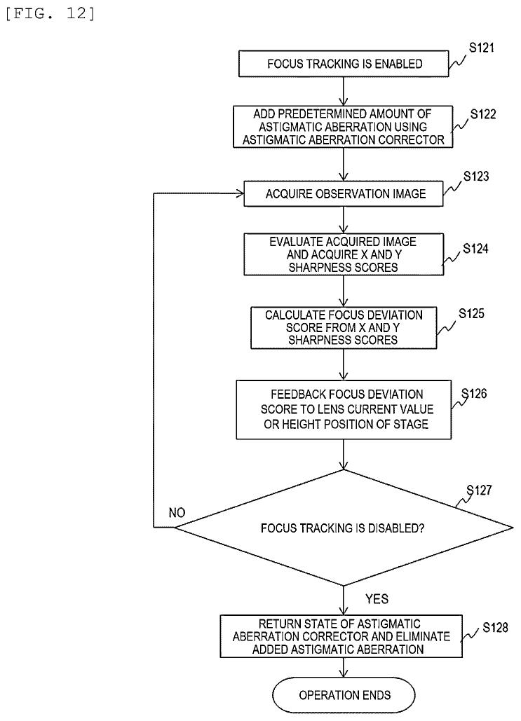

FIG. 13 shows another example of the control flow of the charged particle beam apparatus by the control system 42. In the present example, the control system 42 measures a current astigmatic aberration of the electron optical system instead of adding an astigmatic aberration for calculating the focus deviation score to the electron optical system subjected to the astigmatic aberration correction, and calculates the focus deviation score based on the current astigmatic aberration.

After the electron optical system adjustment of the charged particle beam apparatus is performed, the control system 42 receives the user operation for enabling the focus tracking function (S141), and then acquires an image to measure the astigmatic aberration (S142). The measurement of the astigmatic aberration is a widely known technique, and a detailed description thereof is omitted. For example, the control system 42 can measure the astigmatic aberration of the electron optical system by performing scan with the primary electron beam along two orthogonal axes and causing the astigmatic aberration correction device 14 to maximize a contrast of the image. In addition, when the astigmatic aberration of the optical system is already known at the time of receiving the user operation for enabling the focus tracking function, the already known astigmatic aberration may be used.

Alternatively, it is possible to measure the magnitude of the astigmatic aberration from a result of an autocorrelation function or a cross-correlation function of one or more acquired images, and it is also possible to measure the aberration by determining the focus deviation amount and the value of the astigmatic aberration from images acquired under a plurality of conditions in which an angle of the electron beam incident on the objective lens is changed and performing fitting calculation on a result thereof.

The control system 42 acquires an observation image (S143). The control system 42 evaluates the acquired image and acquires the X and Y sharpness scores (S144). The control system 42 may determine the X axis and the Y axis that acquire the sharpness scores as described above in accordance with the measurement result of the astigmatic aberration. The control system 42 calculates the focus deviation score from the X and Y sharpness scores (S145).

The control system 42 feedbacks the focus deviation score to the objective lens current value or the height position of the sample stage 22 (S146). The control system 42 estimates whether the focus is located on the upper side or the lower side with respect to the sample from the focus deviation score and the measured astigmatic aberration, and also estimates how far the focus is away from the sample as necessary. The relation between the astigmatic aberration and the focus deviation score may be set in advance by the control system 42. The control system 42 controls the objective lens current value or the height position of the sample stage 22 in accordance with the estimation result so that the focus approaches the sample.

While the focus tracking function is enabled (S147: NO), the control system 42 continues to execute steps S143 to S146. When the focus tracking function is disabled (S147: YES), the control system 42 corrects the astigmatic aberration of the electron optical system using the astigmatic aberration correction device 14 (S148).

The focus deviation score is determined based on a relation between the X sharpness score and the Y sharpness score. In the example described above, the control system 42 calculates the focus deviation score by the difference between the X sharpness score and the Y sharpness score. Alternatively, the control system 42 may compare the magnitudes of the scores by another method, and for example, the control system 42 may calculate the focus deviation score using the ratio or the quotient between the X sharpness score and the Y sharpness score. Alternatively, the control system 42 may perform the evaluation described above using a result obtained by adding or subtracting a predetermined offset to or from each of the acquired X sharpness score and Y sharpness score or a result obtained by multiplying the acquired X sharpness score and Y sharpness score by a predetermined coefficient.

When a sample having little change in one direction of the axis on which the sample is evaluated, for example, an edge portion of a film-like sample having a smooth surface or a cross section of a laminated film structure having a uniform structure, is observed, the observation image of the sample does not have a main change in the structure in the one direction. Accordingly, the score of the sharpness with respect to the one direction may change less with respect to change in a probe width in the one direction or change in the relative position between the sample and the focus. In this case, the control system 42 may calculate the focus deviation score based on one sharpness score indicating change with respect to the change in the relative position between the sample and the focus.

For example, the control system 42 may switch the behavior by determining the above-mentioned case by a certain method. As the determination method described above, a plurality of methods may be considered. For example, it is possible to determine a case where one sharpness score is smaller than a threshold value and the other sharpness score is larger than the threshold value or a case where a significant concentration of a correlation value in a specific direction in the autocorrelation function of the image, that is, generation of a peak, is not observed. Alternatively, it is possible to determine such cases using a method such as image recognition or Hough transform. In such a case, the control system 42 determines the sharpness score in a direction having less change in the image as the focus deviation score. It is possible to estimate the direction and the deviation amount of the focus deviation with respect to the sample by comparing the focus deviation score with a preset reference value.

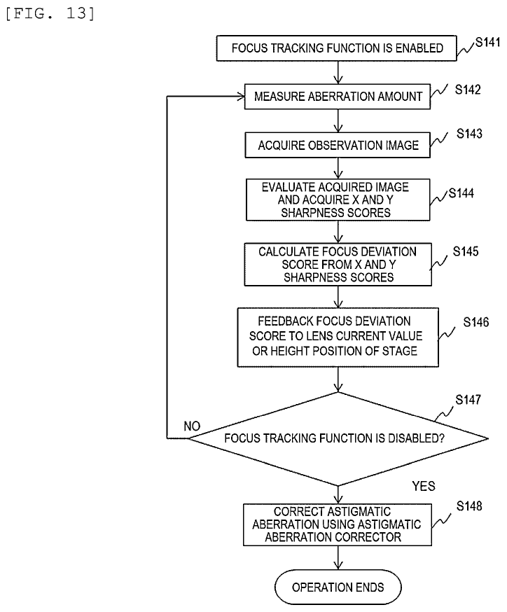

FIG. 14 shows an example of a graphical user interface for the user to control the charged particle beam system. FIG. 14 shows a control screen of the focus adjustment based on the astigmatic aberration. The control system 42 enables the focus tracking function when a check box 501 is checked. When the check is removed from the check box 501, the control system 42 disables the focus tracking function.

The control system 42 determines the direction of the astigmatic aberration to be added to the electron optical system according to an angle input in an input field 502. A reference axis of the angle (axis of 0°) is, for example, the X1 axis or the X2 axis of the astigmatic aberration correction device 14. The control system 42 determines the magnitude of the astigmatic aberration to be added to the electron optical system according to a level selected in a selection list 503. As the astigmatic aberration is larger, a distance between the focus position and a position at which the diameter of the beam cross-sectional shape on the X axis or the Y axis is the smallest is large. It is possible to add the astigmatic aberration suitable for observing a target sample by making it possible to adjust the angle and the magnitude of the astigmatic aberration. In addition, values set in the input fields 502 and 503 may each have a predetermined initial value, and an input unit that performs such setting may be performed on a dedicated screen different from a screen used by the user in a normal operation.

The control system 42 displays an observation image 504 on the control screen. Further, the control system 42 displays in a box 505 a relative position of one of the height position of the sample and a current focus position with the other position as the reference. The example of FIG. 14 shows a focus relative position with reference to the height position of the sample.

When the focus tracking function is disabled, the user can adjust the focus relative position with respect to the height position of the sample by operating an operation knob provided in the control apparatus 40 or the computer 41 or a slider 506 while referring to a numerical value of the box 505. The control system 42 controls the objective lens current or the height of the sample stage in response to the operation.

Next, an example of a method for calculating the sharpness score will be described. An example of the method for calculating the sharpness score uses the wavelet transform or the discrete wavelet transform. In the wavelet transform, an image is transformed into a wavelet (localized small wave/base) that is scaled, repositioned, and superimposed. Therefore, it is possible to evaluate local frequency information while maintaining the position information on the image. In a case where a local region including a structure such as an edge is focused in particular in the sample, when the focus is on the sample, the intensity change of the image of the current region is steep, and an absolute value of a wavelet transformation coefficient increases.

Conversely, when the focus is deviated from the sample, in order to obtain the intensity of the image using information on a region wider than the condition when the focus is on the sample, the intensity change of the image in the current region becomes relatively gradual as a result, and the absolute value of the wavelet transform coefficient becomes small. Therefore, a large absolute value of the wavelet transform coefficient indicates that the focus is close to the sample.

In one example, the control system 42 determines the X sharpness score and the Y sharpness score based on an X direction (horizontal) wavelet transformation coefficient along an X axis at a specific level j+1 and a Y direction (vertical) wavelet transformation coefficient along a Y axis at a specific level j+1, respectively. For example, the control system 42 determines a maximum value of an absolute value of the X direction wavelet transformation coefficient of the level j+1 (for example, a level 1) as the X sharpness score and determines a maximum value of an absolute value of the Y direction wavelet transformation coefficient of the level j+1 as the Y sharpness score.

The maximum value of the absolute value of the wavelet transform coefficient may be determined in data from which noise is removed or an image to which an information restoration process is applied using a neural network or a technique such as compressed sensing. In addition, a plurality of algorithms are known as methods for obtaining the wavelet transform coefficient, and any algorithm can be used. The control system 42 may determine the sharpness scores from wavelet transformation coefficients of a plurality of levels.

It is possible to determine the sharpness scores by a method different from the wavelet transform. For example, it is possible to determine the sharpness scores using a window Fourier transform, a window discrete cosine transform, or a differential filter convolution. For example, a maximum value of a coefficient by the convolution of the differential filter in the X direction with respect to the observation image can be set as the X sharpness score, and a maximum value of a coefficient by the convolution of the differential filter in the Y direction with respect to the observation image can be set as the Y sharpness score. Examples of the differential filter include, for example, a first-order differential filter, a Sobel filter, and a Prewitt filter. As long as the sharpness along the specific axis in the image can be evaluated, the method for calculating the sharpness score is not limited.

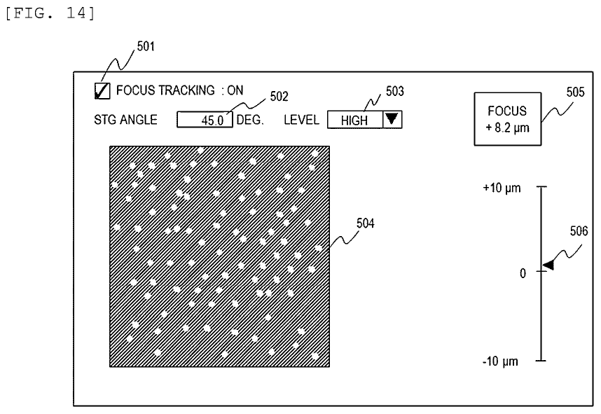

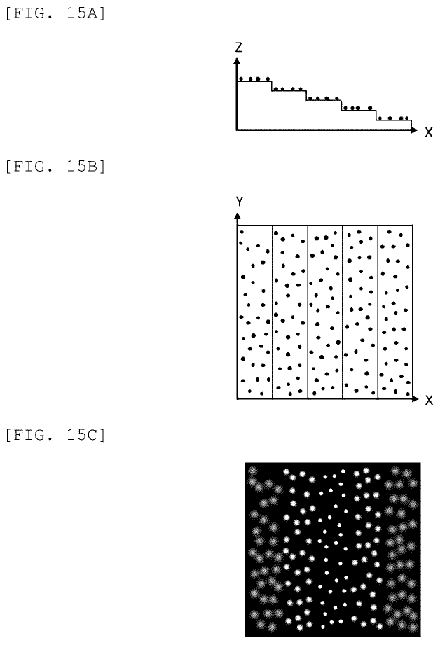

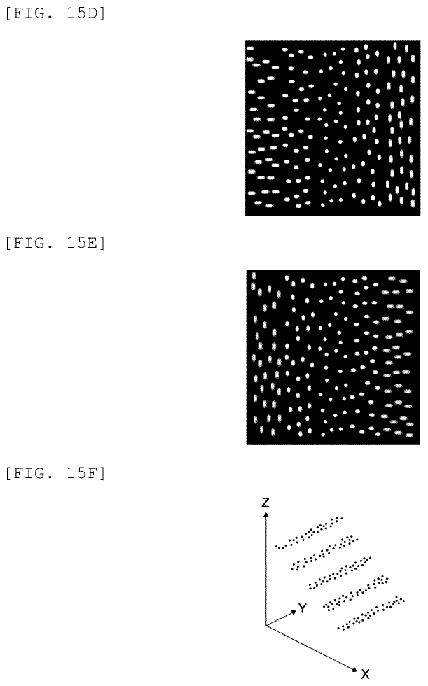

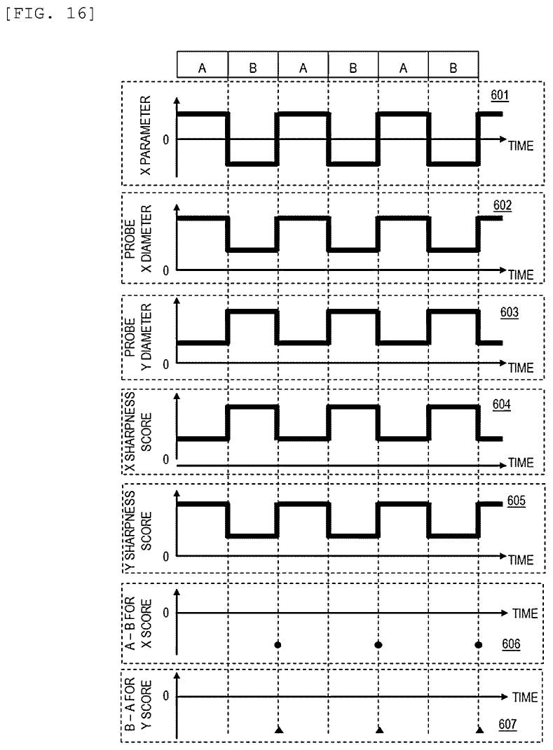

FIGS. 15A to 15F show examples in which height distribution of the sample is performed using evaluated results by the method described above. As one example, when a sample structure has a uniform height in the Y-axis direction and a plurality of heights in the X-axis direction, a cross-sectional structure including the X axis and the Z axis of the sample structure can be expressed as shown in FIG. 15A, and an external appearance when an upper surface of the sample is viewed from the Z-axis direction that is an observation direction can be expressed as shown in FIG. 15B.

The sample surface has a height of five stages, and has a shape in which the height changes in a stepwise manner each time the sample progresses in a positive direction on the X axis. When the sample is observed with the focus in a central portion of the field of view using the charged particle optical system having no astigmatic aberration, an observed image as shown in FIG. 15C can be obtained. On both left and right sides of the field of view, deviation occurs between a focus plane and the sample surface, and thus the observation image is blurred. At this time, since the charged particle optical system has no astigmatic aberration, it is difficult to evaluate a vertical relation between the height of the sample surface and the focus plane from a degree of the blurring in the left and right regions of the observed image.

Meanwhile, when the electron optical system has an astigmatic aberration in which the beam spreads from the focus position toward the upper side in the X direction with respect to the Y direction as shown in FIG. 6, the observation image is as shown in FIG. 15D. In addition, when the electron optical system has an astigmatic aberration in which the beam spreads from the focus position toward the upper side in the Y direction with respect to the X direction, the observed image is as shown in FIG. 15E.

In such a case, by dividing the observation image into a plurality of local regions and evaluating the relation between the focus position and the height position of the sample based on the evaluation of the sharpness as described above in each region, the height distribution of the sample in the field of view can be evaluated from a single image or a plurality of images. Such a result can be displayed by pseudo three-dimensional display as shown in FIG. 15F, which shows the height distribution of the sample surface in a three-dimensional space configured with the X axis, the Y axis, and the Z axis, and the control system 42 can show information on a three-dimensional structure of the sample to the user by a method for displaying height information of the Z-axis direction by replacing the height information with a color.

### Second Embodiment

Hereinafter, another method for determining a sharpness score will be described. The method described above determines sharpness scores along two different axes in one image. In an example described below, the sharpness score along the same axis is calculated in each image in an electron optical system to which different astigmatic aberrations are added, and a relative position between a sample and a focus is estimated based on the sharpness score. Accordingly, it is possible to more appropriately estimate a height position of the sample in which change in a structure along one axis is small. The sharpness score of the image can be calculated as described in the first embodiment. In addition, a focus deviation score can be calculated by various methods as described in the first embodiment.

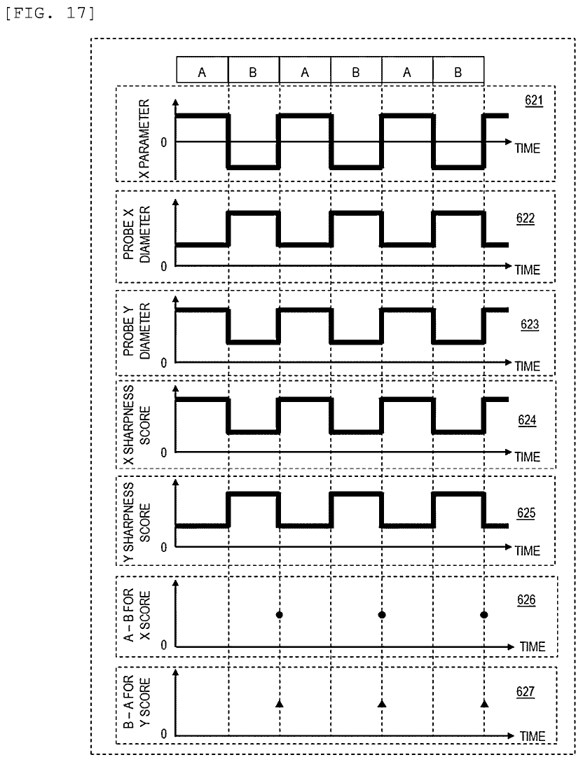

FIG. 16 shows a relation among the astigmatic aberration added to the electron optical system, a diameter of a beam cross-sectional shape, and a score when evaluation is performed by changing an astigmatic aberration amount added to the electron optical system to a plurality of conditions. The present example corresponds to a case in which the height position of the sample is higher than a focus position and the focus position is constant. A graph 601 shows temporal change of an X parameter (X-axis astigmatic aberration correction coil current) of the astigmatic aberration correction device 14 in a state where the astigmatic aberration of the electron optical system is corrected. In the present example, a case in which two positive and negative astigmatism correction amounts are periodically repeated in a time axis direction is shown. Alternatively, the change does not need to be periodic, and each condition may be once alone instead of repeating.

In addition, parameters of the astigmatic aberration correction device are relative. For example, in a case where a certain parameter has already been set for the astigmatic aberration correction device at a time point before starting the temporal change of the X parameter as described above, the temporal change of the X parameter may be performed in a form of being superimposed on a value of the X parameter that has already been set. This similarly applies to a Y parameter, a new parameter that is created by combining the X parameter and the Y parameter at a predetermined ratio, and the like.

A graph 602 shows temporal change in a diameter on the X axis of the beam cross-sectional shape in a plane of the height of the sample. A graph 603 shows temporal change of a diameter on the Y axis of the beam cross-sectional shape. The X parameter is a rectangular wave having positive and negative values. When the value of the X parameter is positive, the diameter on the X axis of an elliptical beam cross-sectional shape is large and the diameter on Y axis is small. When the value of the X parameter is negative, the diameter on the X axis of an elliptical beam cross-sectional shape is small and the diameter on the Y axis is large. A state of the electron optical system in which the X parameter is a positive value is referred to as a state A, and a state of the electron optical system in which the X parameter is a negative value is referred to as a state B. The electron optical system repeats the state A and the state B.

In the description of the present example, when the X parameter is increased, a larger diameter of the beam cross-sectional shape on the upper side of the electron beam converged in the vicinity of the sample is taken as the X axis, and a smaller diameter is taken as the Y axis. As described above, the X axis and the Y axis do not necessarily coincide with two directions in which pixels constituting an observed two-dimensional image are arranged.

A graph 604 shows temporal change in an X sharpness score. A graph 605 shows temporal change in a Y sharpness score. The X sharpness score changes in accordance with change in the diameter on the X axis, and shows a small value when the diameter on the X axis is large (state A) and a large value when the diameter on the X axis is small (state B). The Y sharpness score changes in accordance with change in the diameter on the Y axis, and shows a large value when the diameter on the Y axis is small (state A) and a small value when the diameter on the Y axis is large (state B).

A graph 606 shows a value obtained by subtracting, from the X sharpness score in the state A, the X sharpness score in the immediately preceding state B (X focus deviation score). The X focus deviation score shows a negative value. A graph 607 shows a value obtained by subtracting, from the Y sharpness score in the state B, the Y sharpness score in the immediately preceding state A (Y focus deviation score). The Y focus deviation score shows a negative value.

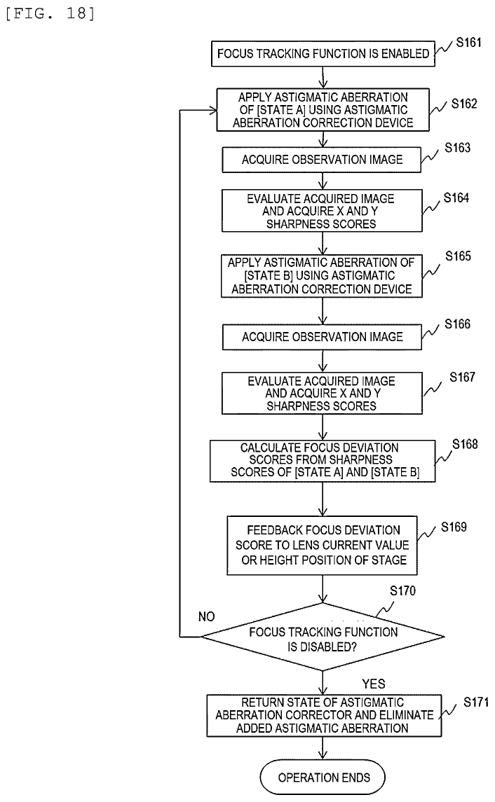

FIG. 17 shows the relation among the astigmatic aberration added to the electron optical system, the diameter of the beam cross-sectional shape, and the score when the sample height position is lower than the focus position. The focus position is constant. A graph 621 shows temporal change of the X parameter (X-axis astigmatic aberration correction coil current) of the astigmatic aberration correction device 14 in a state where the astigmatic aberration of the electron optical system is corrected.

A graph 622 shows temporal change in the diameter on the X axis of the beam cross-sectional shape in the plane of the height of the sample. A graph 623 shows temporal change of the diameter on the Y axis of the beam cross-sectional shape. The X parameter shows a rectangular wave having positive and negative values. When the X parameter is a positive value, the diameter on the X axis of the elliptical beam cross-sectional shape is small and the diameter on the Y axis is large. When the X parameter is a negative value, the diameter on the X axis of an elliptical beam cross-sectional shape is large and the diameter on the Y axis is small. A state of the electron optical system in which the X parameter is a positive value is the state A, and a state of the electron optical system in which the X parameter is a negative value is the state B. The electron optical system repeats the state A and the state B.

A graph 624 shows temporal change in the X sharpness score. A graph 625 shows temporal change in the Y sharpness score. The X sharpness score changes in accordance with the change in the diameter on the X axis, and shows a large value when the diameter on the X axis is small (state A) and a small value when the diameter on the X axis is large (state B). The Y sharpness score changes in accordance with the change in the diameter on the Y axis, and shows a small value when the diameter on the Y axis is large (state A) and a large value when the diameter on the Y axis is small (state B).

A graph 626 shows the value obtained by subtracting, from the X sharpness score in the state A, the X sharpness score in the immediately preceding state B (X focus deviation score). The X focus deviation score shows a positive value. A graph 627 shows a relation between the time and the value obtained by subtracting, from the Y sharpness score in the state B, the Y sharpness score in the immediately preceding state A (Y focus deviation score). The Y focus deviation score shows a positive value.

As described above, both the X focus deviation score and the Y focus deviation score may change in accordance with change in the relative position between the sample and the focus. When the sample has a small change in structure in a specific direction, the sharpness of the image in the direction or the focus deviation score using the sharpness does not show a large change with respect to the change in the relative position between the sample and the focus. In such a case, it is possible to show the relative position between the sample and the focus by using a focus deviation score of the other axis.

When the direction in which structural change of the sample is small and the direction in which the sharpness is evaluated do not coincide with each other, the sharpness in each of the direction in which the structural change of the sample is small and a direction orthogonal thereto includes a component in each of two directions in which the sharpness is evaluated. In this case, it is possible to obtain the same focus deviation score from information on both axial directions in which the sharpness is evaluated, and thus it is possible to show the relative position between the sample and the focus even by using an average or a sum of either of the two focus deviation scores or both of the two focus deviation scores.

For example, when an absolute value of one focus deviation score is smaller than a threshold value and the other focus deviation score is larger than the threshold value, the control system 42 changes the relative position between the sample and the focus in accordance with the other focus deviation score as described in the first embodiment. When both the X and Y focus deviation scores are larger than the threshold value, the control system 42 changes the relative position between the sample and the focus based on any one or both of the focus deviation scores. For example, it is possible to use an average value, a sum, or a larger value of the X and Y focus deviation scores, or dispersion or stability when the score is determined a plurality of times.

In the above-described example, when the focus deviation score shows a negative value, the control system 42 estimates that the height position of the sample is higher than the focus position and further estimates the distance between the height position of the sample and the focus position from the absolute value of the focus deviation score. When the focus deviation score shows a positive value, the control system 42 estimates that the height position of the sample is lower than the focus position and further estimates the distance between the height position of the sample and the focus position from the absolute value of the focus deviation score.

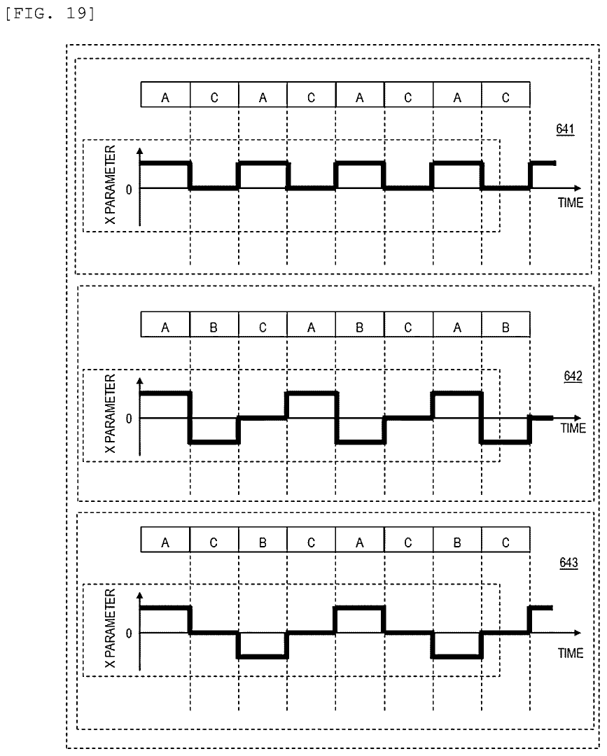

FIG. 18 shows an example of a control flow of the charged particle beam apparatus by the control system 42, which corresponds to the examples shown in FIGS. 16 and 17. Upon detecting that the focus tracking function is enabled, the control system 42 adjusts the relative position between the sample and the focus based on the focus deviation score of an acquired image. Accordingly, it is possible to efficiently align the focus with respect to the sample.

After the electron optical system adjustment of the charged particle beam apparatus is performed, the control system 42 receives the user operation for enabling the focus tracking function (S161), and then adds an astigmatic aberration of the [state A] using the astigmatic aberration correction device 14 (S162). The control system 42 acquires an observation image (S163). The control system 42 evaluates the acquired image and acquires the X and Y sharpness scores (S164).

Next, the control system 42 adds an astigmatic aberration of the [state B] using the astigmatic aberration correction device 14 (S165). The control system 42 acquires an observation image (S166). The control system 42 evaluates the acquired image and acquires the X and Y sharpness scores (S167). The control system 42 calculates the X focus deviation score from the X sharpness scores of the [state A] and the [state B] and calculates the Y focus deviation score from the Y sharpness scores of the [state A] and the [state B] (S168).

As described above, the control system 42 performs feedback control of the objective lens current value or the height position of the sample stage 22 based on one or both of the X and Y focus deviation scores (S169). The control system 42 estimates, from the focus deviation score, the positional relation between the sample and the focus, specifically, whether the focus is located on the upper side or the lower side with respect to the sample and how far the focus is away from the sample. The control system 42 controls the objective lens current value or the height position of the sample stage 22 in accordance with the estimation result so that the focus approaches the sample.

While the focus tracking function is enabled (S170: NO), the control system 42 continues to execute steps S162 to S169. When the focus tracking function is disabled (S170: YES), the control system 42 returns a state of the astigmatic aberration correction device 14 to a state before the astigmatic aberration is added, and eliminates the added astigmatic aberration (S171).

In the above-described example, the focus deviation score is calculated after the sharpness of the state B is evaluated. In another example, each time the state is switched, the focus deviation score may be calculated from the sharpness score in the current state and the immediately preceding state. The control system 42 may perform the focus adjustment shown in FIG. 18 in response to the user operation of the sample stage 22 for moving the field of view. The control system 42 may display the estimation result of the relative position between the focus and the sample by the focus deviation score acquired by the above-described method without automatically performing the focus adjustment.

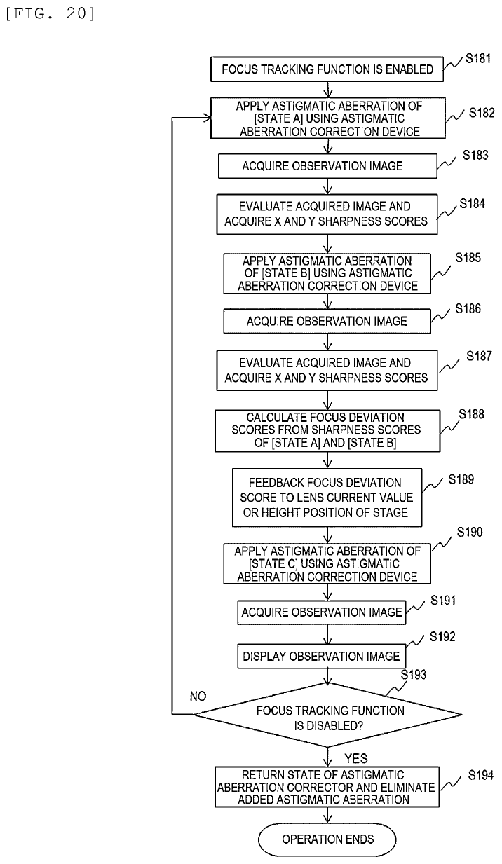

FIG. 19 shows the relation among the astigmatic aberration added to the electron optical system, the diameter of the beam cross-sectional shape, and the score when evaluation of the focus deviation in a state where the astigmatic aberration is added and display of an observation image acquired in a state where the astigmatic aberration is not added are performed apparently at the same time. A graph 641 shows the temporal change of the X parameter (X-axis astigmatic aberration correction coil current) of the astigmatic aberration correction device 14 in a state where the astigmatic aberration of the electron optical system is corrected.

When the X parameter is set to a value other than zero, a constant astigmatic aberration is added to the charged particle optical system [state A]. When the X parameter is zero, no additional astigmatic aberration is added to the charged particle optical system and the charged particle optical system returns to the state in which the astigmatic aberration is corrected [state C]. In the [state A], the evaluation of the focus deviation alone is performed by using the above-described method, and the acquired image is not displayed. In the [state C], by only displaying the acquired image, the user using the apparatus can evaluate the focus deviation without feeling that the astigmatic aberration is apparently added.

Accordingly, as in the case of a normal operation, the user can adjust the field of view while checking the image in a state in which the astigmatic aberration of the apparatus is adjusted. At the same time, the user can use the apparatus while automatically continuously adjusting the focus deviation. In addition, as another example, the focus deviation may be evaluated using both an evaluation result of the image acquired in the [state C] and an evaluation result of the image acquired in the [state A].

In addition, as shown in a graph 642, the [state A] and the [state B] in which different X parameters are set in the astigmatic aberration correction device 14 and the [state C] in which the X parameter is zero are sequentially set. Accordingly, it is possible to evaluate the focus deviation by changing the astigmatism correction amount to a plurality of conditions by the above-described method, and at the same time, it is possible for the user to continue showing the image alone in the state in which the astigmatic aberration is adjusted. In this case, the evaluation of the focus deviation is preferable to be performed based on the evaluation results of the [state A] and the [state B], and may also be performed using the evaluation results of two conditions or three conditions among the [state A], the [state B], and the [state C].

In addition, as shown in a graph 643, it is also possible to set the [state C] between repeated setting of two states of the [state A] and the [state B] in which different X parameters are set in the astigmatic aberration correction device 14. In this case, it is possible to acquire the image in the [state C] at a frequency twice that of the control shown in the graph 642, and thus it is possible to improve an update frequency of the image when the user uses the image.

FIG. 20 shows a specific control flow at the time of evaluating the focus deviation by applying the control of the X parameter shown in the graph 642 of FIG. 19 described above to the astigmatic aberration correction device 14. A basic flow is the same as the flow described in FIG. 18. The control system 42 calculates the focus deviation scores from the sharpness scores acquired in the [state A] and the [state B] (S188), and then feedbacks the results to the lens current or the height position of the stage (S189). Thereafter, the control system 42 adds an astigmatic aberration of the [state C] to the astigmatic aberration correction device 14 (S190) to return to a state in which the astigmatic aberration is adjusted, acquires the observed image in the state (S191), and displays the obtained observed image (S192).

By repeating this series of flow, the user can automatically adjust the observed image acquired in the [state C] displayed in S192 to a state in which the focus deviation is decreased while confirming the observed image alone, and can continue to maintain this state. When the user changes the observation field of view during the execution of this flow, the feedback (S189) corresponding to the change is performed, so that the focus is always kept automatically in an appropriately adjusted state in the observation field of view.

In addition, in the above-described example, the example in which the image is acquired under a plurality of conditions in which the astigmatic aberration amount is changed has been described. Alternatively, the same control may be performed using a score alone for one direction obtained from a one-dimensional signal obtained by performing scan with an electron beam in one direction instead of the image.

The invention is not limited to the above-described embodiments, and includes various modifications. For example, the above-described embodiments are described in detail for easy understanding of the invention, and the invention is not necessarily limited to those including all the configurations described above. A part of a configuration of one embodiment can be replaced with a configuration of another embodiment, and a configuration of another embodiment can be added to the configuration of the one embodiment. Further, a part of the configuration of each embodiment may be added to, deleted from, or replaced with another configuration.

Further, a part or all of the above-described configurations, functions, process units, and the like may be implemented by hardware such as through design using an integrated circuit. The above-described configurations, functions, or the like may also be implemented by software by interpreting and performing a program for implementing respective functions by a processor. Information on programs, tables, files, or the like for implementing each function can be placed in a recording device such as a memory, a hard disk, and a solid-state drive (SSD), or a recording medium such as an IC card and an SD card.

Further, control lines and information lines show those considered to be necessary for the description, and not all the control lines and the information lines are necessarily shown on the product. In practice, it may be considered that almost all configurations are connected to each other.

1. A charged particle beam system comprising:
a charged particle beam apparatus configured to irradiate, via a charged particle optical system, a sample with a charged particle beam from a charged particle source; and
a control system configured to control the charged particle beam apparatus, wherein
the control system is configured to
evaluate, with respect to a signal obtained by irradiating the sample with the charged particle beam via the charged particle optical system having an astigmatic aberration, a score based on an index that changes in accordance with a spatial spread of the charged particle beam, and
determine a positional relation between a height position of the sample and a convergence plane of the charged particle beam based on the astigmatic aberration of the charged particle optical system and a result of the evaluation.

2. The charged particle beam system according to claim 1, wherein
the signal is an image signal.

3. The charged particle beam system according to claim 1, wherein
the index represents a sharpness.

4. The charged particle beam system according to claim 1, wherein
a direction of the astigmatic aberration is known in the control system.

5. The charged particle beam system according to claim 1, wherein
the control system is configured to evaluate scores in a plurality of axial directions.

6. The charged particle beam system according to claim 5, wherein
the plurality of axial directions are two axial directions orthogonal to each other.

7. The charged particle beam system according to claim 5, wherein
the control system is configured to compare magnitudes of the respective scores in the plurality of axial directions in the evaluation.

8. The charged particle beam system according to claim 5, wherein
the control system is configured to calculate any one of a difference, a ratio, and a quotient of the scores.

9. The charged particle beam system according to claim 1, wherein
the signal is acquired under a plurality of different astigmatic aberration conditions.

10. The charged particle beam system according to claim 9, wherein
the plurality of different astigmatic aberration conditions are a plurality of astigmatic aberration conditions having the same direction and different magnitudes.

11. The charged particle beam system according to claim 9, wherein
the plurality of different astigmatic aberration conditions are a plurality of astigmatic aberration conditions having the same magnitude and different directions.

12. The charged particle beam system according to claim 9, wherein
the control system is configured to evaluate the score by comparing magnitudes of respective scores acquired under the plurality of different astigmatic aberration conditions.

13. The charged particle beam system according to claim 9, wherein
the control system is configured to calculate any one of a difference, a ratio, and a quotient of scores.

14. The charged particle beam system according to claim 12, wherein
the comparison of the magnitudes is performed for scores in the same direction.

15. The charged particle beam system according to claim 1, wherein
the control system is configured to add an astigmatic aberration to the charged particle optical system in which the former astigmatic aberration is corrected.

16. The charged particle beam system according to claim 1, wherein
the control system is configured to display information on the positional relation on a display device.

17. The charged particle beam system according to claim 1, wherein
the control system is configured to control at least one of the height position of the sample and a convergence position of the charged particle beam based on the positional relation such that a difference between the height position of the sample and the convergence plane of the charged particle beam is reduced.

18. The charged particle beam system according to claim 1, wherein
the score is determined using any one of a differential filter, a Sobel filter, a Prewitt filter, a wavelet transform, a discrete wavelet transform, a Fourier transform, a discrete cosine transform, and a correlation function.

19. A method executed by a control system of a charged particle beam apparatus, the method comprising:
evaluating, with respect to a signal obtained by irradiating a sample with a charged particle beam via a charged particle optical system having an astigmatic aberration, a score based on an index that changes in accordance with a spatial spread of the charged particle beam; and
determining a positional relation between a height position of the sample and a convergence plane of the charged particle beam based on the astigmatic aberration of the charged particle optical system and a result of the evaluation.
